(19) United States
(12) Patent Application Publication
(10) Pub. No.: US 2004/0195470 A1
(43) Pub. Date: Oct. 7, 2004

(54) Adapter for votive candle holder

(76) Inventor: Sanjeev Kumar, Munster, IN (US)

Correspondence Address: OLSON & HIERL, LTD., 36th Floor, 20 North Wacker Drive, Chicago, IL, 60606, US

(21) Appl. No.: 10/406,111

(22) Filed: Apr. 3, 2003

(51) Int. Cl. H05K 5/02

(52) U.S. Cl. 248/127; 248/345; 362/358

(57) ABSTRACT

A lampshade adapter for a votive candle holder including a lower band or ring for seating the adapter over the upper rim of the votive candle holder. An upper band or ring located above the lower ring and supported by rods extending between the lower and upper rings allows a lampshade to be suspended over the votive candle holder.

### FIELD OF THE INVENTION

The present invention relates to votive candle holders and, more particularly, to an adapter which allows a shade to be suspended over the votive candle holder.

### BACKGROUND OF THE INVENTION

Various embodiments of ornamental votive candle holders have been in widespread use, many of which include a generally cylindrical housing within which a votive sized candle is adapted to be seated.

The present invention is directed to an adapter which allows a shade to be suspended over the votive candle holder to simulate the look of a miniature table lamp.

### SUMMARY OF THE INVENTION

The present invention is a lampshade adapter for a votive candle holder comprising an endless band having an outer perimeter and an inwardly extending flange for abutting the upper rim of a votive candle holder and defining a flange aperture. The adapter also comprises a plurality of upstanding support rods secured to the outer perimeter of the endless band, and a support ring situated above the inwardly extending flange which is held in place by the support rods.

In one embodiment, the endless band has a diameter greater than the diameter of the support ring. The rods converge inwardly from the endless band into the support ring. A separate, removable lampshade including a lower rim and an upper rim having an inwardly extending flange is adapted to be lowered over the adapter into abutting relationship with the support ring of the adapter for supporting and suspending the lampshade over the votive candle holder. The lampshade can include a shade body which is unitary with the support ring of the adapter.

### BRIEF DESCRIPTION OF THE DRAWINGS

In the drawings:

FIG. 1 is a perspective view of an adapter/shade structure of the present invention suspended over the top rim of a votive candle holder;

FIG. 2 is a vertical cross-sectional view of FIG. 1;

FIG. 3 is a perspective view of the adapter of the present invention;

FIG. 4 is an exploded plan view of FIG. 1;

FIG. 5 is a broken perspective view of an alternate embodiment of the present invention wherein the adapter is unitary with the shade; and

FIG. 6 is a bottom plan view of the alternate embodiment of FIG. 5.

### DETAILED DESCRIPTION OF THE PREFERRED EMBODIMENT OF THE INVENTION

The invention disclosed herein is, of course, susceptible of embodiment in many different forms. Shown in the drawings and described herein below in detail is a preferred embodiment of the adapter and shade structure of the present invention. It is to be understood, however, that the present disclosure is an exemplification of the principles of the invention and does not limit the invention to the illustrated embodiment.

For ease of description, the adapter of the present invention is described herein below in its usual position seated over the top rim of a votive candle holder and terms such as upper, lower, vertical, etc., will be used herein with reference to this seated position.

Moreover, it is understood that the FIGURES herein do not necessarily show details of the adapter, the shade, or the votive candle holder that are known in the art and that will be recognized by those skilled in the art as such. The detailed descriptions of such elements are not necessary to an understanding of the invention. Accordingly, such elements are herein represented only to the degree necessary to aid in an understanding of the features of the present invention.

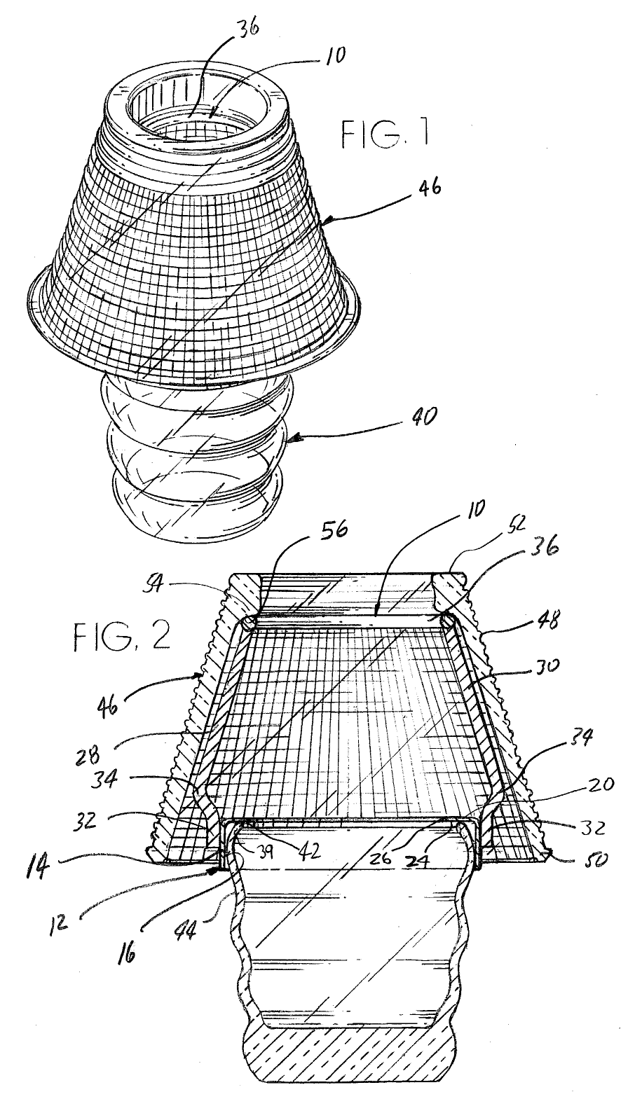

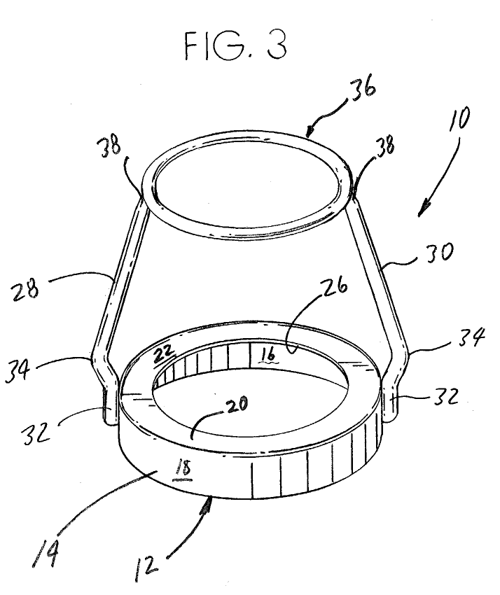

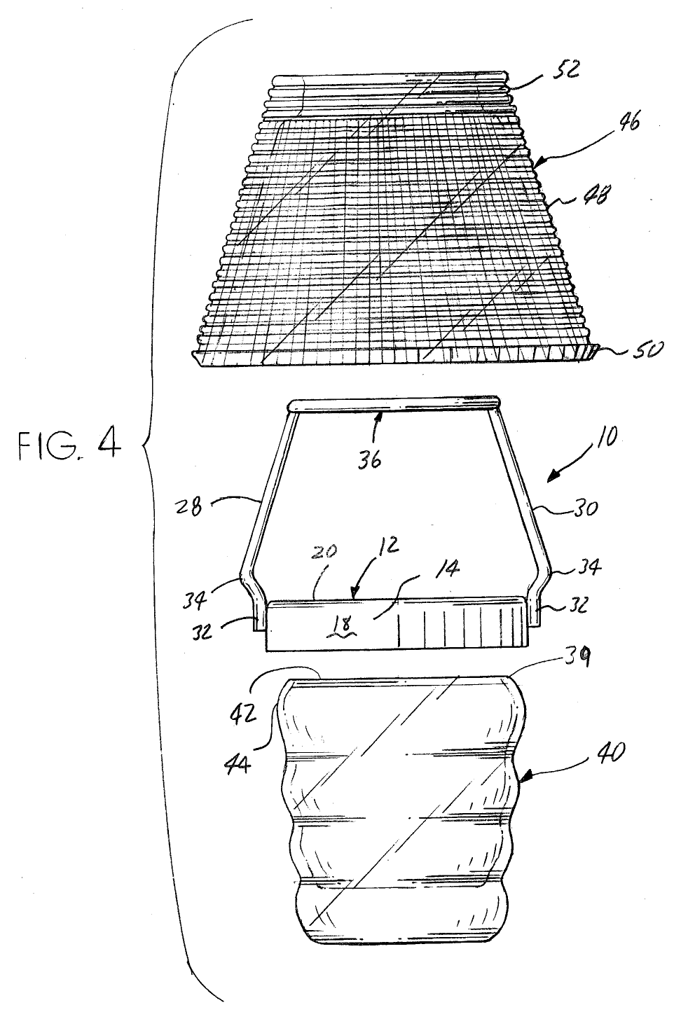

FIGS. 1-4 depict the votive candle holder adapter 10 of the present invention which allows a shade 46 to be suspended over a votive candle holder 40 so as to simulate the look of a miniature table lamp. Particularly and, as shown in FIGS. 2 and 3, the adapter structure 10 is made of metal or the like and comprises initially a bottom base 12 which, in the embodiment shown, is in the form of an endless metal band or ring which includes an outer perimeter or peripheral, generally vertically oriented, lip member 14 which has inner and outer faces 16 and 18 respectively. The base 12 further incorporates a flange member 20 which, in the embodiment shown, extends generally radially horizontally unitarily inwardly from the top of the inner face 16 of the vertical lip member 12. The flange member 20 includes upper and lower faces 22 and 24 respectively and further an inner cylindrical rim 26 defining an interior generally cylindrically shaped flange aperture.

The adapter 10 further comprises supports which, in the embodiment shown, are in the form of a pair of diametrically opposed elongate and upstanding support rods 28 and 30 each including lower ends 32 which are secured, as by welding or the like, to the outer face 18 of the lip 14 of the base 12. The rods 28 and 30 extend convergingly upwardly from the lip 14 and each includes an outward curve or bend 34 formed adjacent and fore of the respective lower ends 32 thereof secured to the lip 14.

The adapter 10 still further comprises a top which, in the embodiment shown, is in the form of a generally horizontally oriented tubular metal support ring 36 which extends between and is held in place, by welding or the like, to the respective diametrically opposed upper ends 38 of the support rods 28 and 30 respectively. The ring 36 is spaced from, supported above, and positioned generally parallel to, the base 12. In the embodiment shown, the diameter of the base 12 is greater than the diameter of the support ring 36.

In accordance with the present invention, and as shown in FIG. 2, the adapter 10 is seated over an upper rim 39 of the glass votive candle holder 40 in a relationship where the lower face 24 of the flange 20 of the base 12 is in abutting relationship with the generally horizontal top face 42 of the upper rim 39 of the votive candle holder 40 and the inner face 16 of the lip 14 of the base 12 surrounds and abuts against the outer perimeter of the portion of the side face 44 of the votive candle holder 40 which is located adjacent the upper rim 39 thereof.

Although not shown in any of the drawings, it is understood that the adapter may be made from any suitable material, preferably metal, and that the base 12 may be sized to accommodate votive candle holders having rims of varying diameters simply by increasing the width of the flange 20 relative to the lip 14. For example, the width of the flange 20 can be increased thereby increasing the distance between the rim 26 and the lip 14 to accommodate any size votive candle holder. The lip/flange structure of the base 12 is but one suitable structure for securing and seating the adapter 10 to or over the top of the votive candle holder 40. This invention also encompasses other suitable alternate base structures such as, for example, a base structure incorporating clips or prongs adapted to be clipped to the rim 39 of the votive candle holder 40 or, alternatively, a base 12 defining an inverted U-shaped groove adapted to receive the rim 39 of the votive candle holder 40.

As also shown in FIGS. 1-3, a cover 46 which, in the embodiment shown, is in the form of a glass lampshade adapted to be fitted and suspended over the top of the adapter 10 and, more specifically, over the ring 36 and surrounding the rods 28 and 30. Referring to FIG. 2 in particular, the cover 46 includes a circumferentially extending shade body 48 defining a lower cylindrical open rim 50 and an upper top cylindrical open rim 52 including an inwardly radially extending flange 54 having a lower face 56. The cover 46 is adapted to be fitted over the adapter 10 in a relationship wherein the lower face 56 of the flange 54 is positioned in abutting relationship with the top of the ring 56, the shade body 48 of the cover 46 surrounds the rods 28 and 30 and the lower rim 50 extends over and covers the upper rim 39 of the votive candle holder 40.

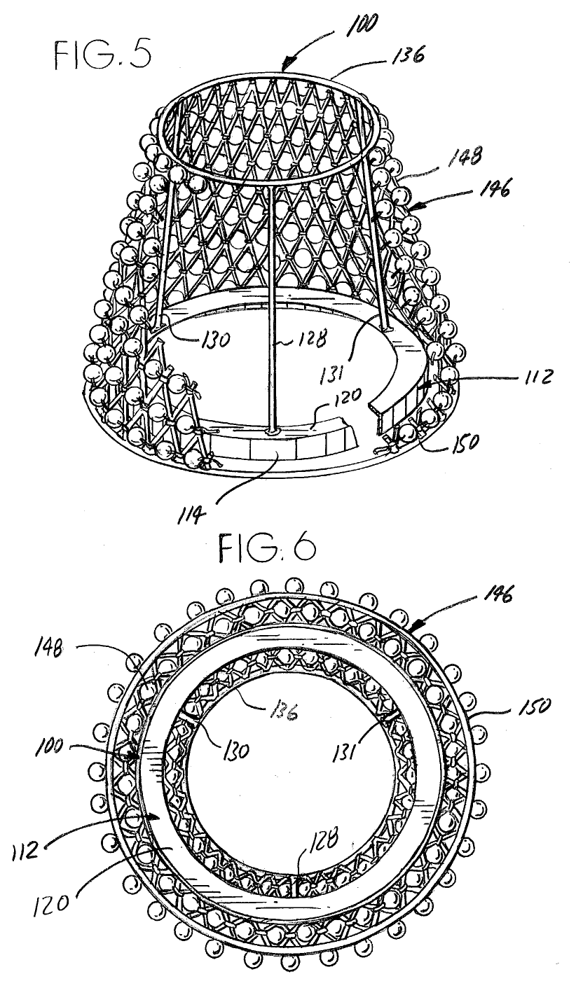

Although the drawings depict the embodiment of the present invention wherein the cover or shade is a component separate from the adapter, the cover or shade can be formed unitary with the adapter as shown in FIGS. 5 and 6, if desired.

Particularly, the adapter 100 depicted in FIGS. 5 and 6 differs in structure from the adapter 10 depicted in FIGS. 1-4 in that the top support ring 136 of the adapter 100 is unitary with the shade 146 surrounding the adapter 100 and serves two functions, i.e., as the top support ring of the adapter 100 and further as the top rim of the shade 146 unitary therewith. In accordance with this alternate embodiment, the shade body 148 extends and diverges circumferentially unitarily downwardly from the support ring 136 and terminates in a lower circumferentially extending rim 150 which is spaced from the bottom base 112 of the adapter 100 and is positioned approximately horizontally co-planarly with the bottom of the lip member 114 of the base 112 of the adapter 100.

The adapter 100 also differs from the adapter 10 in that the base 112 has a greater diameter than the base 12 and the adapter 100 includes three equi-distally spaced-apart upstanding support rods 128, 130 and 131 extending between the top flange member 120 of the base 112 and the top ring 136.

The adapter 10 constructed in accordance with the present invention thus allows any votive candle holder to replicate the look of a miniature table lamp complete with a lampshade. It is also readily apparent from the foregoing detailed description of the invention and from the illustrations thereof that numerous variations and modifications may be effected to the adapter 10 without departing from the true spirit and scope of the novel concepts or principles of the present invention.

I claim:

1. A lampshade adapter for a votive candle holder and comprising an endless band having an outer perimeter and an inwardly extending flange for abutting the upper rim of a votive candle holder and defining a flange aperture;
a plurality of upstanding lampshade support rods secured to the outer perimeter of the endless band; and
a support ring situated above the inwardly extending flange and held in place by the lampshade support rods.

2. The lampshade adapter of claim 1 wherein the endless band has a diameter greater than the diameter of the support ring and the rods converge inwardly from the endless band into the support ring.

3. The lampshade adapter of claim 1 further comprising a lampshade including a lower rim and an upper rim having an inwardly extending flange adapted to abut against the support ring for suspending the lampshade over the votive candle holder.

4. An adapter for securing a lampshade over a votive candle holder including an upper rim and the adapter comprising:
a bottom ring adapted to fit over the upper rim of the votive candle holder;
a top ring spaced from the bottom ring and adapted to support the lampshade; and
rods between and interconnecting the bottom ring to the top ring.

5. The adapter of claim 4 wherein the bottom ring includes a peripheral lip adapted to surround the upper rim of the votive candle holder and a flange adapted to abut against the top of the upper rim of the votive candle holder.

6. The adapter of claim 4 wherein the bottom ring has a diameter greater than the diameter of the top ring and the rods converge inwardly between the bottom ring and the top ring.

7. The adapted of claim 4 wherein the lampshade includes an upper rim having an inwardly extending flange adapted to abut against the top ring.

8. The adapter of claim 5 wherein the rods are secured and extend upwardly from the peripheral lip of the bottom ring.

9. An adapter for securing a lampshade over a votive candle holder including an upper rim and the adapter comprising:
a base adapted to be fitted over to the upper rim of a votive candle holder;
a top spaced from the base and adapted to support and suspend the lampshade over the votive candle holder; and
support rods between and interconnecting the base and the top.

10. The adapter of claim 9 wherein the base is a ring adapted to be seated over the upper rim of the votive candle holder.

11. The adapter of claim 9 wherein the top is a ring.

12. The adapter of claim 9 wherein the lampshade includes an upper rim defining an inwardly extending flange and the lampshade is removably supported over the top of the adapter in a relationship wherein the flange of the lampshade abuts against the top of the adapter.

13. The adapter of claim 9 wherein the lampshade includes a shade body which is unitary with the top of the adapter and extends between the base and the top of the adapter.
